(19) United States
(12) Patent Application Publication
(10) Pub. No.: US 2025/0160080 A1
(43) Pub. Date: May 15, 2025

(54) PIXEL STRUCTURE

(71) Applicant: AUO Corporation, Hsinchu (TW)

(72) Inventors: Kuan-Lin Chiu, Hsinchu (TW); Han-Chung Lai, Hsinchu (TW); Cheng-Han Chung, Hsinchu (TW); Yu-Cheng Chang, Hsinchu (TW)

(73) Assignee: AUO Corporation, Hsinchu (TW)

(21) Appl. No.: 18/534,729

(22) Filed: Dec. 11, 2023

(30) Foreign Application Priority Data
Nov. 14, 2023 (TW) 112143906

(51) Int. Cl. H01L 33/62; H01L 25/075

(52) U.S. Cl. CPC H10H 20/857; H01L 25/0753

(57) ABSTRACT

A pixel structure includes a first conductive layer, a second conductive layer, and multiple light-emitting elements. The first conductive layer includes multiple conductive pattern groups and a connection pattern. Each conductive pattern group includes a first conductive pattern and a second conductive pattern, and the first conductive pattern is island-shaped. Second conductive patterns of the conductive pattern groups are directly connected to the connection pattern. The second conductive layer includes multiple pad groups. A first pad and a second pad of each pad group are respectively overlapped with and are electrically connected to the first conductive pattern and the second conductive pattern of the conductive pattern group. In a top view of the pixel structure, at least one first pad overlaps at least one first conductive pattern and a portion of the connection pattern.

### CROSS-REFERENCE TO RELATED APPLICATION

This application claims the priority benefit of Taiwan application serial no. 112143906, filed on Nov. 14, 2023. The entirety of the above-mentioned patent application is hereby incorporated by reference herein and made a part of this specification.

### BACKGROUND

### Technical Field

This disclosure relates to a pixel structure.

### Description of Related Art

A light-emitting diode (LED) display panel consists of a driver backplane and a number of light-emitting diode elements transferred on the driver backplane. Inheriting the characteristics of light-emitting diodes, the light-emitting diode display panel has advantages such as power saving, high efficiency, high brightness, and fast response time. In addition, compared to an organic light-emitting diode display panel, the light-emitting diode display panel has the advantages of easy color adjustment, long light-emitting life, and no image imprinting, etc. Thus, the light-emitting diode display panel is regarded as the next generation of display technology.

Generally speaking, in the manufacturing process of the light-emitting diode display panel, laser bonding technology can be utilized to melt the solder in order to bond the electrodes of the light-emitting diode components with the pads of the driver backplane. However, during the above laser bonding process, the solder may easily absorb too little energy, resulting in false soldering problems and dark spots on the light-emitting diode display panel.

### SUMMARY

The disclosure provides a pixel structure, capable of improving bonding yields.

The disclosure provides another pixel structure, capable of improving bonding yields.

The pixel structure according to an embodiment of the disclosure includes a first conductive layer, a first insulating layer, a second conductive layer, and multiple light-emitting elements. The first conductive layer includes multiple conductive pattern groups and a connection pattern. Each of the conductive pattern groups includes a first conductive pattern and a second conductive pattern, and the first conductive pattern is island-shaped. Second conductive patterns of the conductive pattern groups are directly connected to the connection pattern. The first insulating layer is disposed on the first conductive layer. The second conductive layer is disposed on the first insulating layer. The second conductive layer includes multiple pad groups. Each of the pad groups includes a first pad and a second pad. The first pad and the second pad of the each of the pad groups are respectively overlapped with and electrically connected to the first conductive pattern and the second conductive pattern of the conductive pattern group. The connection pattern is located outside an area of second pads of the pad groups. Each of the light-emitting elements has a first electrode and a second electrode. The first electrode and the second electrode of the each of the light-emitting elements are electrically connected to the first pad and the second pad of the pad group respectively. In a top view of the pixel structure, at least one first pad is overlapped with at least one first conductive pattern and a portion of the connection pattern.

The pixel structure according to another embodiment of the disclosure includes a first conductive layer, a first insulating layer, a second conductive layer, multiple light-emitting elements, a third conductive layer, and a second insulating layer. The first conductive layer includes multiple conductive pattern groups and a connection pattern. Each of the conductive pattern groups includes a first conductive pattern and a second conductive pattern, and the first conductive pattern is island-shaped. Second conductive patterns of the conductive pattern groups are directly connected to the connection pattern. The first insulating layer is disposed on the first conductive layer. The second conductive layer is disposed on the first insulating layer. The second conductive layer includes multiple pad groups. Each of the pad groups includes a first pad and a second pad. The first pad and the second pad of the each of the pad groups are respectively overlapped with and electrically connected to the first conductive pattern and the second conductive pattern of the conductive pattern group. The connection pattern is located outside an area of second pads of the pad groups. Each of the light-emitting elements has a first electrode and a second electrode. The first electrode and the second electrode of the each of the light-emitting elements are respectively electrically connected to the first pad and the second pad of the pad group. The first conductive layer is disposed between the second conductive layer and the third conductive layer. The second insulating layer is disposed between the first conductive layer and the third conductive layer. The third conductive layer includes a third conductive pattern. In a top view of the pixel structure, at least a portion of the third conductive pattern is located outside the pad groups.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate example embodiments of the disclosure and, together with the description, serve to explain the principles of the disclosure.

FIG. 1 is a schematic top view of a pixel structure according to an embodiment of the disclosure.

FIG. 2 is a schematic top view of a first conductive layer of the pixel structure according to an embodiment of the disclosure.

FIG. 3 is a schematic cross-sectional view of a display panel according to an embodiment of the disclosure.

FIG. 4 shows temperature distribution of multiple first pads and multiple second pads according to an embodiment of the disclosure in FIG. 1.

FIG. 5 is a top view of a pixel structure of a comparative example.

FIG. 6 shows temperature distribution of multiple first pads and multiple second pads in the comparative example of FIG. 5.

FIG. 7 is a schematic top view of a pixel structure according to another embodiment of the disclosure.

FIG. 8 is a schematic top view of a first conductive layer of a pixel structure according to another embodiment of the disclosure.

FIG. 9 is a schematic cross-sectional view of a display panel according to another embodiment of the disclosure.

FIG. 10 shows temperature distribution of multiple first pads and multiple second pads according to another embodiment of the disclosure in FIG. 7.

FIG. 11 is a schematic top view of a pixel structure according to yet another embodiment of the disclosure.

FIG. 12 is a schematic top view of a first conductive layer of the pixel structure according to yet another embodiment of the disclosure.

FIG. 13 shows temperature distribution of multiple first pads and multiple second pads according to yet another embodiment of the disclosure in FIG. 11.

FIG. 14 is a top view of a pixel structure of another comparative example.

FIG. 15 shows temperature distribution of multiple first pads and multiple second pads in another comparative example of FIG. 14.

FIG. 16 is a schematic top view of a pixel structure according to still another embodiment of the disclosure.

FIG. 17 is a schematic top view of a first conductive layer of the pixel structure according to still another embodiment of the disclosure.

FIG. 18 is a schematic cross-sectional view of a display panel according to still another embodiment of the disclosure.

FIG. 19 shows temperature distribution of multiple first pads and multiple second pads according to still another embodiment of the disclosure in FIG. 16.

FIG. 20 is a schematic top view of a pixel structure according to an embodiment of the disclosure.

FIG. 21 is a schematic top view of a pixel structure according to another embodiment of the disclosure.

FIG. 22 is a schematic top view of a first conductive layer of the pixel structure according to another embodiment of the disclosure.

FIG. 23 is a schematic cross-sectional view of a display panel according to another embodiment of the disclosure.

FIG. 24 shows temperature distribution of multiple first pads and multiple second pads according to another embodiment of the disclosure in FIG. 21.

### DESCRIPTION OF THE EMBODIMENTS

Reference will now be made in detail to the exemplary embodiments of the disclosure, examples of which are illustrated in the accompanying drawings. Whenever possible, the same reference numerals are used in the drawings and descriptions to refer to the same or similar parts.

It should be understood that when an element such as a layer, film, region, or substrate is referred to as being “on” or “connected to” another element, it can be directly on or connected to the another element, or intermediate elements may also be present. In contrast, when an element is referred to as being “directly on” or “directly connected to” another element, there are no intermediate elements present. As used herein, “connected” may refer to physical and/or electrical connection. Furthermore, “electrical connection” or “coupled” may mean the presence of other elements between the two elements.

As used herein, “about,” “approximately,” or “substantially” includes the stated value and the average within an acceptable range of deviations from the particular value as determined by person having ordinary skill in the art, taking into account the measurements in question and a specific amount of error associated with a measurement (i.e., the limitations of the measurement system). For example, “about” may mean within one or more standard deviations of the stated value, or within ±30%, ±20%, ±10%, ±5%. Furthermore, the terms “about”, “approximately” or “substantially” used herein may be used to select a more acceptable deviation range or standard deviation based on optical properties, etching properties, or other properties, and one standard deviation may not apply to all properties.

Unless otherwise defined, all terms (including technical and scientific terms) used herein have the same meaning as commonly understood by person having ordinary skill in the art. It should be further understood that terms such as those defined in commonly used dictionaries should be construed to have meanings consistent with their meanings in the context of the relevant technology and the disclosure, and are not be construed to have idealized or overly formalized meanings, unless explicitly so defined herein.

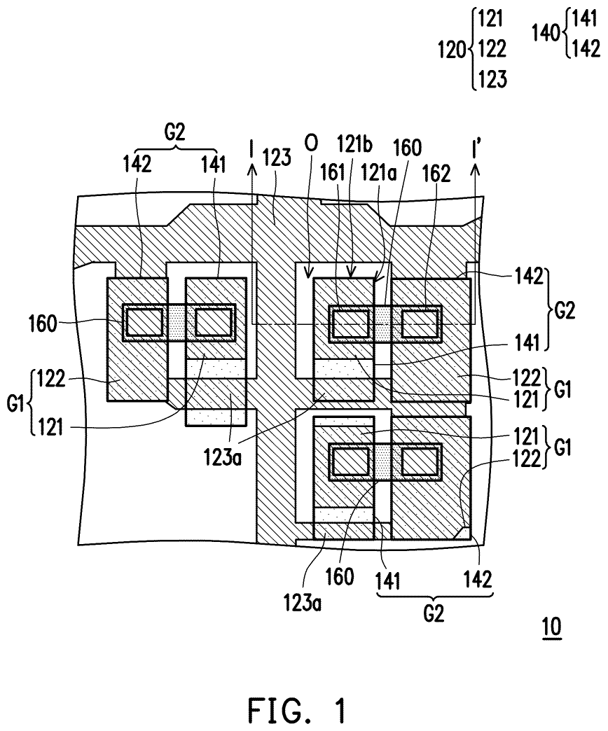

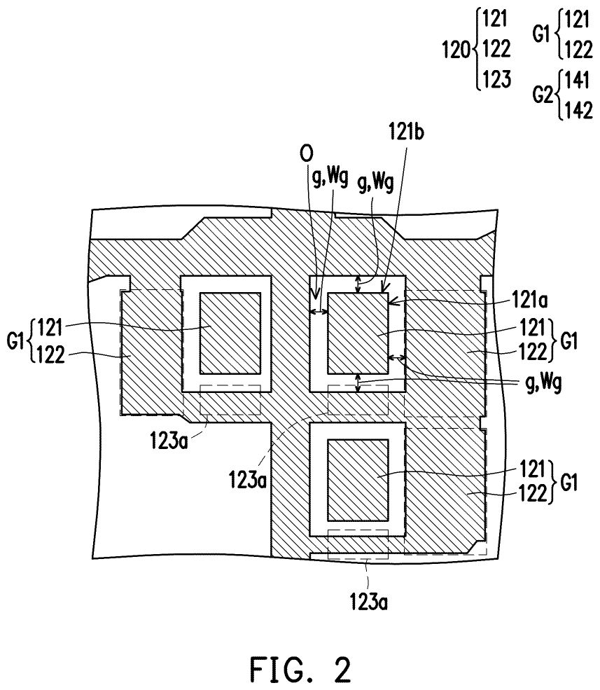

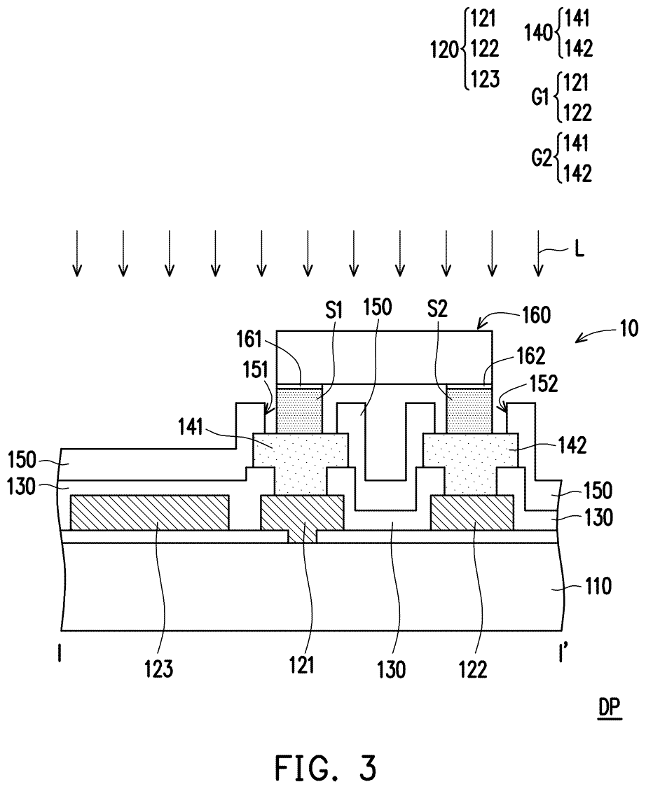

FIG. 1 is a schematic top view of a pixel structure according to an embodiment of the disclosure. FIG. 2 is a schematic top view of a first conductive layer of the pixel structure according to an embodiment of the disclosure. FIG. 3 is a schematic cross-sectional view of a display panel according to an embodiment of the disclosure. FIG. 3 corresponds to a section line I-I′ of FIG. 1.

Referring to FIG. 1 and FIG. 3, a display panel DP includes a substrate 110 and a pixel structure 10 disposed on the substrate 110. The substrate 110 includes a carrying substrate (not shown) and a driving circuit layer (not shown) disposed on the carrying substrate, and the pixel structure 10 is electrically connected to the driving circuit layer of the substrate 110.

Referring to FIG. 1, FIG. 2, and FIG. 3, the pixel structure 10 includes a first conductive layer 120 disposed on the substrate 110, a first insulating layer 130 disposed on the first conductive layer 120, and a second conductive layer 140 disposed on the first insulating layer 130. The first insulating layer 130 is located between the second conductive layer 140 and the first conductive layer 120.

The first conductive layer 120 includes multiple conductive pattern groups G1 and a connection pattern 123. Each of the conductive pattern groups G1 includes a first conductive pattern 121 and a second conductive pattern 122. The first conductive pattern 121 of the each of the conductive pattern groups G1 is island-shaped. That is, first conductive patterns 121 of the conductive pattern groups G1 are electrically independent of each other. Second conductive patterns 122 of the conductive pattern groups G1 are directly connected to the same connection pattern 123. That is, the second conductive patterns 122 are connected in series with each other. For example, in this embodiment, a material of the first conductive layer 120 may be metal, alloy, or a combination of the above, but the disclosure is not limited thereto.

The second conductive layer 140 includes multiple pad groups G2. Each of the pad groups G2 includes a first pad 141 and a second pad 142. The first pad 141 and the second pad 142 of the each of the pad groups G2 are respectively overlapped with and electrically connected to the first conductive pattern 121 and the second conductive pattern 122 of the conductive pattern group G1. The connection pattern 123 is located outside an area of the second pads 142 of the pad groups G2. That is, the connection pattern 123 of the first conductive layer 120 is not obscured by the second pads 142 of the second conductive layer 140.

Each first pad 141 may be overlapped with a corresponding first conductive pattern 121 and a portion 123a of the connection pattern 123. When a light-emitting element 160 emits light, the first conductive pattern 121 and the portion 123a of the connection pattern 123 overlapping the same first pad 141 have different signals. In this embodiment, an overlapping area of the first conductive pattern 121 of the conductive pattern group G1 and a corresponding first pad 141 is smaller than an overlapping area of the second conductive pattern 122 of the same conductive pattern group G1 and a corresponding second pad 142. For example, in this embodiment, a material of the second conductive layer 140 may be metal, alloy, or a combination of the above, but the disclosure is not limited thereto.

The pixel structure 10 also includes multiple light-emitting elements 160. For example, in this embodiment, the pixel structure 10 may include three light-emitting elements 160 for emitting three different colors of light, e.g., red light, green light, and blue light, but the disclosure is not limited thereto. In this embodiment, the light-emitting element 160 is, for example, a micro light-emitting diode (pLED), but the disclosure is not limited thereto.

Each light-emitting element 160 has a first electrode 161 and a second electrode 162. The first electrode 161 and the second electrode 162 of the each light-emitting element 160 are electrically connected to the first pad 141 and the second pad 142 of one pad group G2 respectively. Specifically, in this embodiment, the pixel structure 10 further includes an insulating layer 150 disposed on the second conductive layer 140. The insulating layer 150 has multiple openings 151 and 152 overlapping the first pad 141 and the second pad 142 respectively. The first electrode 161 and the second electrode 162 of the light-emitting element 160 may be electrically connected to the first pad 141 and the second pad 142 through multiple solders (such as but not limited to: tin) S1 and S2 located in the openings 151 and 152 respectively. In this embodiment, a laser bonding process can be used to bond the light-emitting element 160 and the pad group G2.

It should be noted that in a top view of the pixel structure 10, the first conductive pattern 121 of each conductive pattern group G1 has multiple adjacent and non-parallel edges 121a and 121b. The connection pattern 123 and the second conductive pattern 122 of the same conductive pattern group G1 are provided at least next to the edges 121a and 121b of the first conductive pattern 121. There is not any other component of the first conductive layer 120 between the edges 121a and 121b of the first conductive pattern 121 and the connection pattern 123 and between the edges 121a and 121b of the first conductive pattern 121 and the second conductive pattern 122 of the same conductive pattern group G1. That is, at least two edges 121a and 121b of an independent first conductive pattern 121 of the each conductive pattern group G1 are directly adjacent to the second conductive pattern 122 of the same conductive pattern group G1 and a connection pattern 123 for connecting multiple second conductive patterns 122 of multiple conductive pattern groups G1 in series.

When a laser L used to bond the light-emitting element 160 and the pad group G2 is irradiated toward the substrate 110 from the side where the light-emitting element 160 is located, the unshielded connection pattern 123 absorbs the laser L and heats up significantly. Although the first conductive pattern 121 is island-shaped and is not directly connected to the heated connection pattern 123, the first conductive pattern 121 is susceptible to being warmed to a higher temperature by the connection pattern 123 because at least one edge 121b of the first conductive pattern 121 is directly adjacent to the connection pattern 123. Thus, the first pad 141 connected to the independent first conductive pattern 121 may have a sufficient temperature to enable the first electrode 161 of the light-emitting element 160 to be well bonded to the first pad 141 through the solder S1.

In this embodiment, in a top view of the pixel structure 10, the first conductive pattern 121 of the each conductive pattern group G1 may be surrounded by the second conductive pattern 122 of the same conductive pattern group G1 and the connection pattern 123. In other words, the second conductive pattern 122 and the connection pattern 123 of the conductive pattern group G1 may surround a closed opening O, and the first conductive pattern 121 of the same conductive pattern group G1 is disposed in the closed opening O and is island-shaped.

In this embodiment, the second conductive pattern 122 of the conductive pattern group G1 and the connection pattern 123 have the opening O surrounding the first conductive pattern 121 of the same conductive pattern group G1. A circumference of the opening O is greater than one-half of a circumference of the first conductive pattern 121. That is, more than one-half of the edge of the independent first conductive pattern 121 is directly adjacent to the second conductive pattern 122 and connection pattern 123.

In this embodiment, the second conductive pattern 122 of the conductive pattern group G1 and the connection pattern 123 have the opening O surrounding the first conductive pattern 121 of the same conductive pattern group G1, and there is a gap between the opening O and the first conductive pattern 121 of the conductive pattern group G1. A width Wg of the gap g is less than one-quarter of the circumference of the first conductive pattern 121 of the conductive pattern group G1.

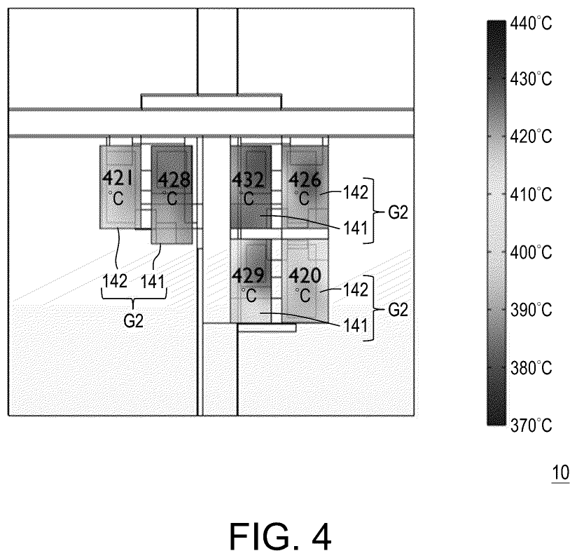

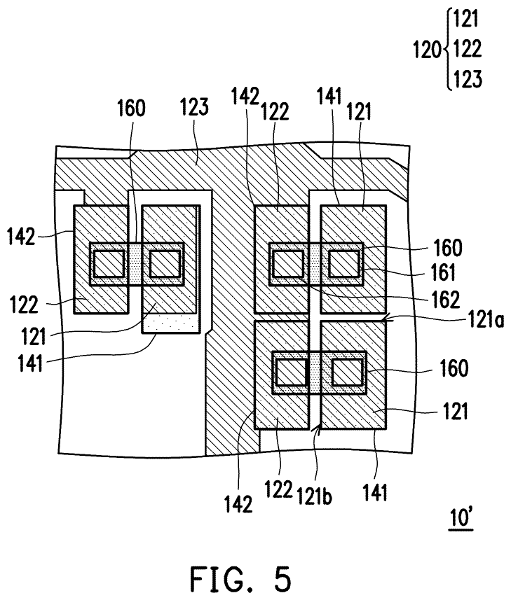

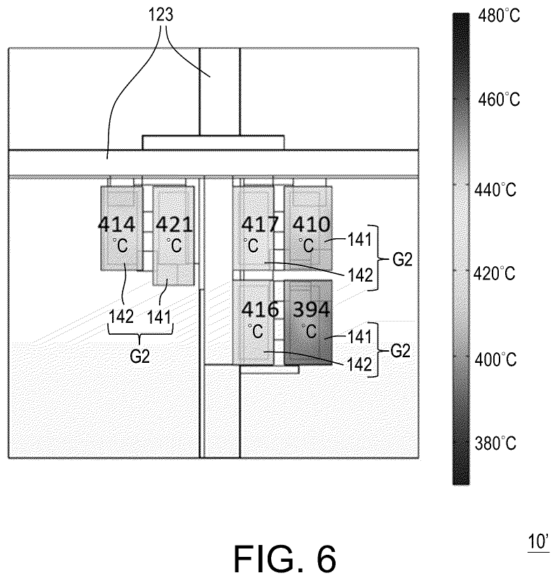

FIG. 4 shows temperature distribution of multiple first pads and multiple second pads according to an embodiment of the disclosure in FIG. 1. FIG. 5 is a top view of a pixel structure of a comparative example. FIG. 6 shows temperature distribution of multiple first pads and multiple second pads in the comparative example of FIG. 5.

A pixel structure 10′ of the comparative example of FIG. 5 is similar to the pixel structure 10 of the embodiment of FIG. 1. One of the differences between the two is that in the embodiment of FIG. 1, the at least two edges 121a and 121b of the independent first conductive pattern 121 of the each conductive pattern group G1 are directly adjacent to the second conductive pattern 122 of the same conductive pattern group G1 and the connection pattern 123, and there is not any other component of the first conductive layer 120 between the edges 121a and 121b of the first conductive pattern 121 and the connection pattern 123 and between the edges 121a and 121b of the first conductive pattern 121 and the second conductive pattern 122 of the same conductive pattern group G1; however, in the embodiment of FIG. 5, at least two edges 121a and 121b of the independent first conductive pattern 121 of at least one conductive pattern group G1 are not directly adjacent to the second conductive pattern 122 of the same conductive pattern group G1 and the connection pattern 123, and there is a first conductive pattern 121 of another conductive pattern group G1 between at least one edge 121a of the first conductive pattern 121 of the at least one conductive pattern group G1 and the connection pattern 123.

Comparing temperature distributions on the first pads 141 in FIG. 6 of the comparative example and FIG. 4 of this embodiment, it can be seen that under the same laser bonding conditions, the temperature of the first pads 141 of the pixel structure 10 of FIG. 1 and FIG. 4 of this embodiment is higher, the temperature of the first pads 141 of the pixel structure 10′ of FIG. 5 and FIG. 6 of the comparative example is lower, and the temperature on the first pads 141 and the second pads 142 of the pixel structure 10 of FIG. 1 and FIG. 4 of this embodiment are close to each other. It can be demonstrated that the design of the pixel structure 10 of the embodiment of FIG. 1 does help to increase the temperature of the pad group G2, which in turn improves the bonding yield between the light-emitting element 160 and the pad group G2.

It must be noted here that the following embodiments follow the reference numerals and part of the content of the foregoing embodiments, where the same reference numerals are used to represent the same or similar elements, and descriptions of the same technical content are omitted. The descriptions of omitted parts may be referred to the foregoing embodiments, which will not be repeated in the following.

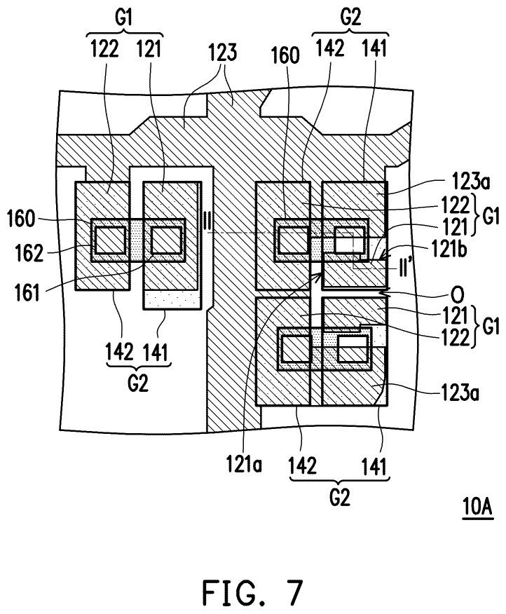

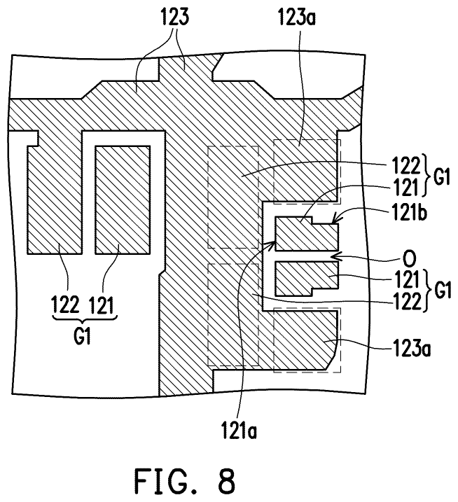

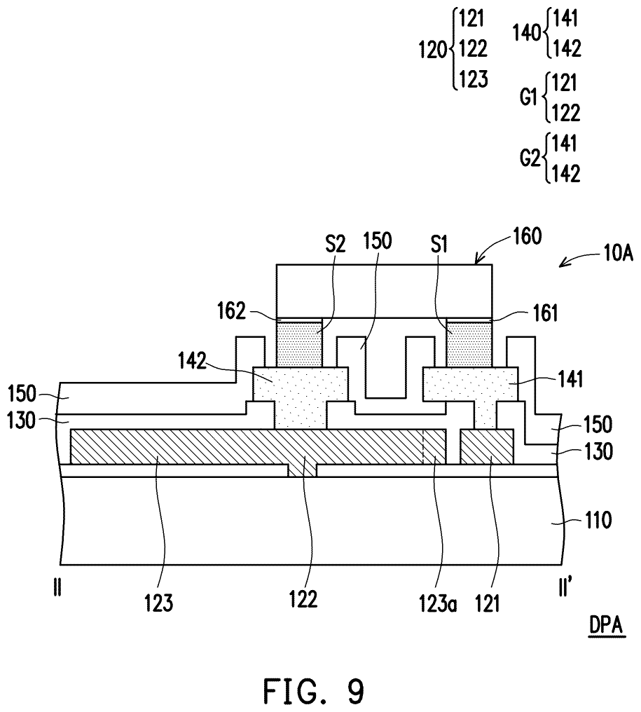

FIG. 7 is a schematic top view of a pixel structure according to another embodiment of the disclosure. FIG. 8 is a schematic top view of a first conductive layer of a pixel structure according to another embodiment of the disclosure. FIG. 9 is a schematic cross-sectional view of a display panel according to another embodiment of the disclosure. FIG. 9 corresponds to a section line II-II′ of FIG. 7.

Referring to FIG. 7, FIG. 8, and FIG. 9, a display panel DPA and a pixel structure 10A thereof are similar to the display panel DP and the pixel structure 10 thereof. At least two edges 121a and 121b of the independent first conductive pattern 121 of the each conductive pattern group G1 are directly adjacent to the second conductive pattern 122 of the same conductive pattern group G1 and the connection pattern 123. The first pad 141 of at least one pad group G2 overlaps the first conductive pattern 121 and the portion 123a of the connection pattern 123. The main difference between the two is that the opening O enclosed by the second conductive pattern 122 and the connection pattern 123 of the each conductive pattern group G1 is an open opening.

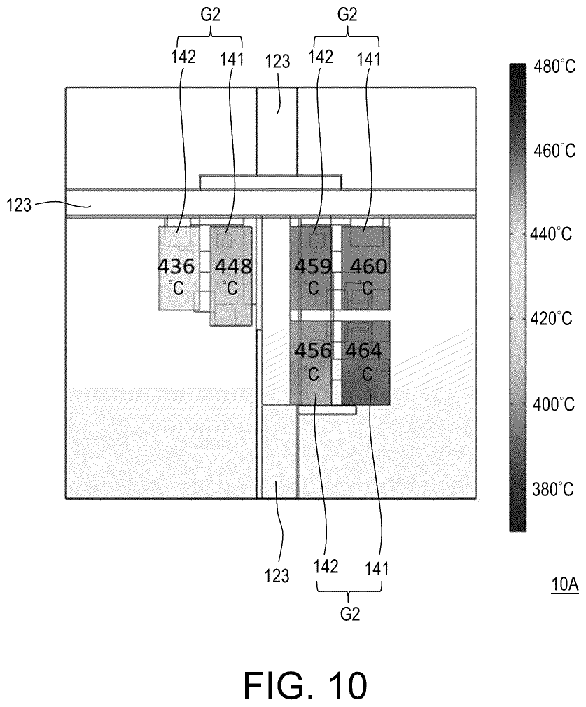

FIG. 10 shows temperature distribution of multiple first pads and multiple second pads according to another embodiment of the disclosure in FIG. 7. Comparing temperature distributions on the first pads 141 in FIG. 5 and FIG. 6 of the comparative example and FIG. 7 and FIG. 10 of this embodiment, it can be seen that under the same laser bonding conditions, the temperature of the first pads 141 of the pixel structure 10A of FIG. 7 and FIG. 10 of this embodiment is higher, the temperature of the first pads 141 of the pixel structure 10′ of FIG. 5 and FIG. 6 of the comparative example is lower, and the temperature on the first pads 141 and the second pads 142 of the pixel structure 10A of FIG. 7 and FIG. 10 of this embodiment are close to each other. It can be demonstrated that the design of the pixel structure 10A of the embodiment does help to increase the temperature of the pad group G2, which in turn improves the bonding yield between the light-emitting element 160 and the pad group G2.

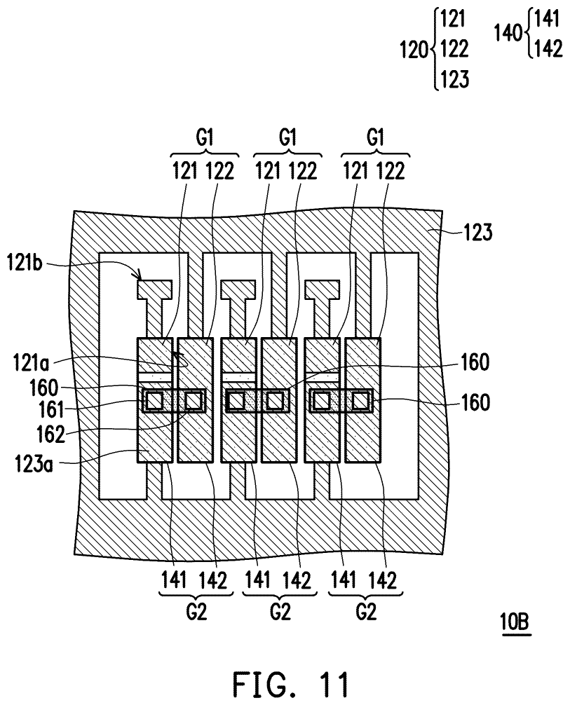

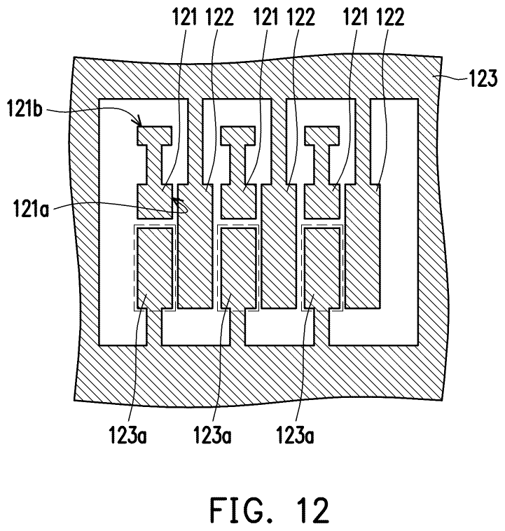

FIG. 11 is a schematic top view of a pixel structure according to yet another embodiment of the disclosure. FIG. 12 is a schematic top view of a first conductive layer of the pixel structure according to yet another embodiment of the disclosure. Referring to FIG. 11 and FIG. 12, a pixel structure 10B of this embodiment is similar to the pixel structure 10. At least two edges 121a and 121b of the independent first conductive pattern 121 of the each conductive pattern group G1 are directly adjacent to the second conductive pattern 122 of the same conductive pattern group G1 and the connection pattern 123, and the first pad 141 of at least one pad group G2 overlap with the first conductive pattern 121 and a portion 123a of the connection pattern 123. The main difference between the two is that the arrangement of the first pads 141 and the second pads 142 of the pad groups G2 of the pixel structures 10 and 10B are arranged in different ways. Specifically, in the embodiment of FIG. 1, the first pads 141 and the second pads 142 of the pad groups G2 of the pixel structure 10 are arranged in multiple columns and rows; however, in the embodiment of FIG. 11, the first pads 141 and the second pads 142 of the pad groups G2 of the pixel structure 10B are arranged in the same rows.

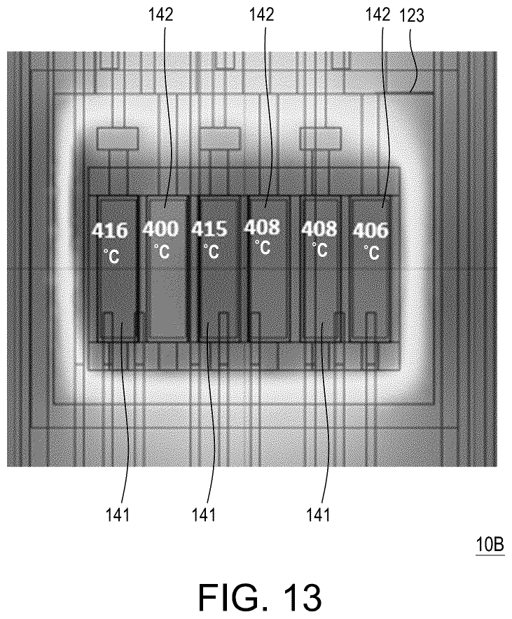

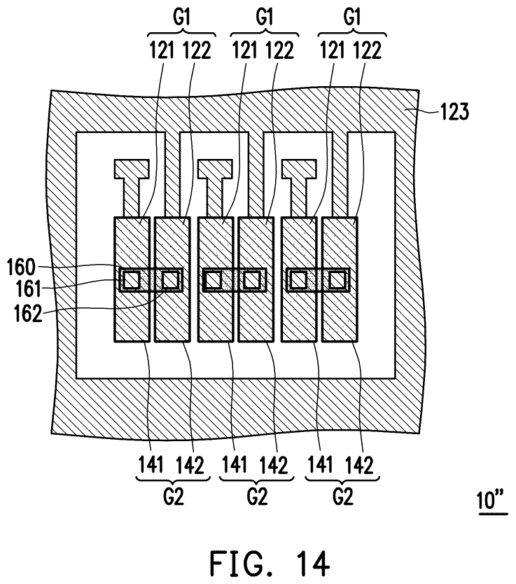

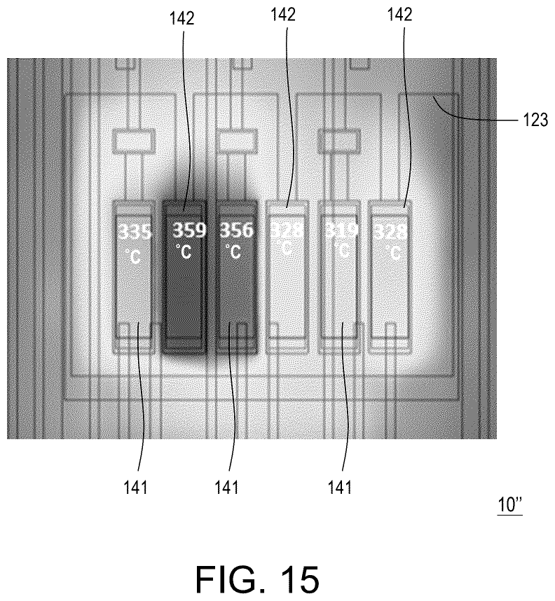

FIG. 13 shows temperature distribution of multiple first pads and multiple second pads according to yet another embodiment of the disclosure in FIG. 11. FIG. 14 is a top view of a pixel structure of another comparative example. FIG. 15 shows temperature distribution of multiple first pads and multiple second pads in another comparative example of FIG. 14. A pixel structure 10″ of the comparative example in FIG. 14 is similar to the pixel structure 10B of the embodiment of FIG. 11. The difference between the two is that in the embodiment of FIG. 11, an area of the first conductive pattern 121 is reduced, in an area given over by the first conductive pattern 121, a portion 123a of the connection pattern 123 is disposed, and the portion 123a of the connection pattern 123 overlaps the first pad 141. Comparing temperature distributions on the first pads 141 in FIG. 14 and FIG. 15 of the comparative example and FIG. 11 and FIG. 13 of this embodiment, it can be seen that under the same laser bonding conditions, the temperature of the first pads 141 of the pixel structure 10B of FIG. 11 and FIG. 13 of this embodiment is higher, the temperature of the first pads 141 of the pixel structure 10″ of FIG. 14 and FIG. 15 of the comparative example is lower, and the temperature on the first pads 141 and the second pads 142 of the pixel structure 10B of FIG. 11 and FIG. 13 of this embodiment are close to each other. It can be demonstrated that the design of the pixel structure 10B of the embodiment does help to increase the temperature of the pad group G2, which in turn improves the bonding yield between the light-emitting element 160 and the pad group G2.

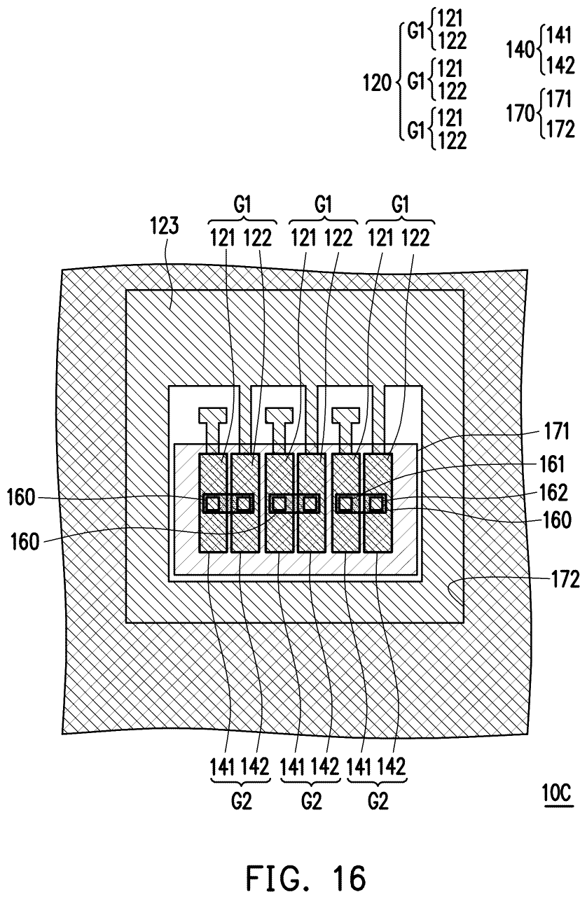

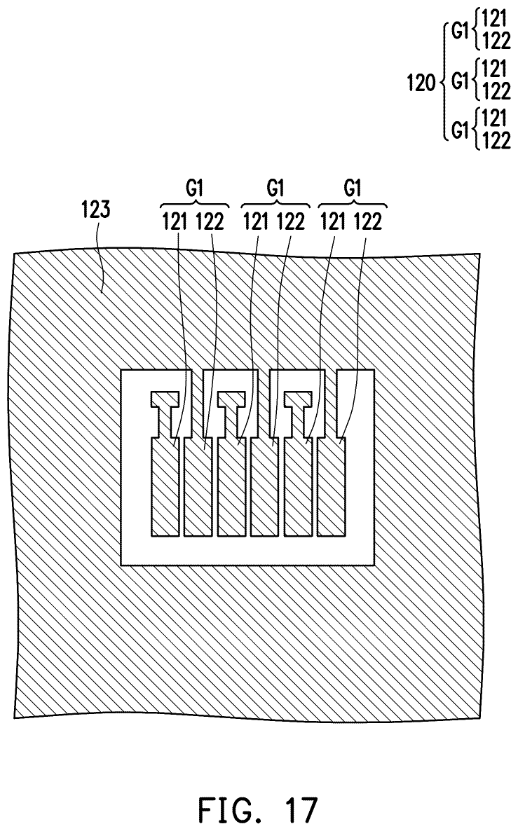

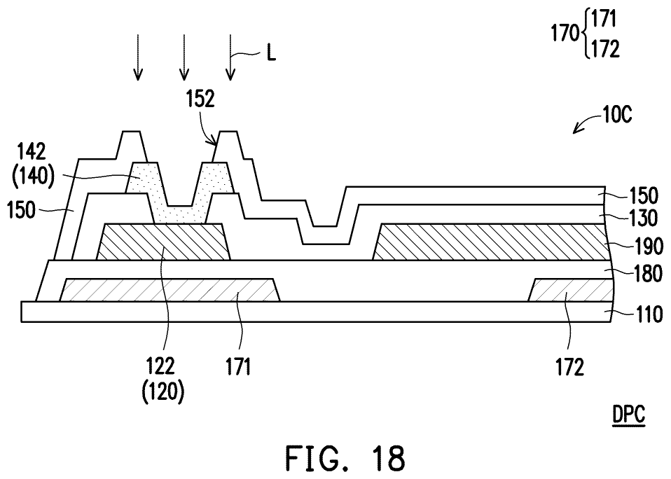

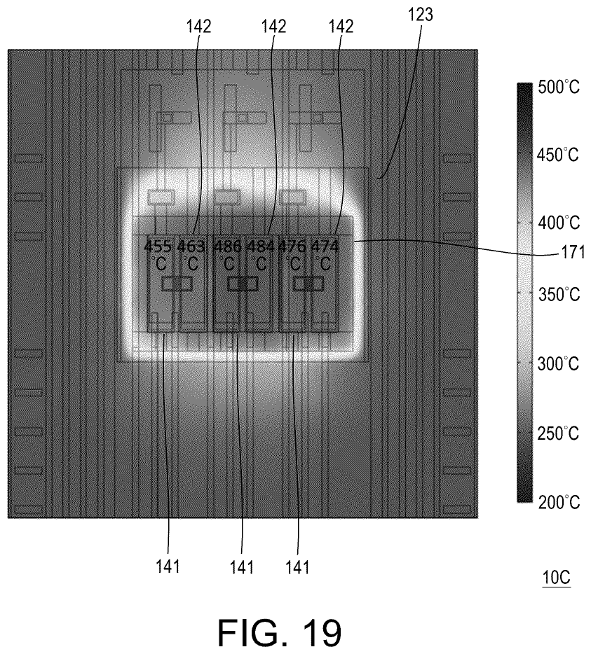

FIG. 16 is a schematic top view of a pixel structure according to still another embodiment of the disclosure. FIG. 17 is a schematic top view of a first conductive layer of the pixel structure according to still another embodiment of the disclosure. FIG. 18 is a schematic cross-sectional view of a display panel according to still another embodiment of the disclosure. FIG. 18 shows the substrate 110, a third conductive layer 170, a second insulating layer 180, a first conductive layer 120, a fourth conductive pattern 190, a first insulating layer 130, a second conductive layer 140, and an insulating layer 150, while other components are omitted. FIG. 19 shows temperature distribution of multiple first pads and multiple second pads according to still another embodiment of the disclosure in FIG. 16.

Referring to FIG. 16, FIG. 17, and FIG. 18, a display panel DPC includes a substrate 110 and a pixel structure 10C disposed on the substrate 110. The pixel structure 10C includes a first conductive layer 120, a first insulating layer 130, a second conductive layer 140, multiple light-emitting elements 160, a third conductive layer 170, and a second insulating layer 180. The first insulating layer 130 is disposed on the first conductive layer 120. The second conductive layer 140 is disposed on the first insulating layer 130. The first conductive layer 120 is disposed between the second conductive layer 140 and the third conductive layer 170. The second insulating layer 180 is disposed between the first conductive layer 120 and the third conductive layer 170. The first conductive layer 120 includes multiple conductive pattern groups G1 and a connection patterns 123. Each of the conductive pattern groups G1 includes a first conductive pattern 121 and a second conductive pattern 122, and the first conductive pattern 121 is island-shaped. The second conductive patterns 122 of the conductive pattern groups G1 are directly connected to the connection pattern 123. The second conductive layer 140 includes multiple pad groups G2. Each of the pad groups G2 includes a first pad 141 and a second pad 142. The first pad 141 and the second pad 142 of the each of the pad groups G2 are respectively overlapped with and electrically connected to the first conductive pattern 121 and the second conductive pattern 122 of a corresponding conductive pattern group G1. The connection pattern 123 is located outside areas of the second pads 144 of the pad groups G2. Each of the light-emitting elements 160 has a first electrode 161 and a second electrode 162. The first electrode 161 and the second electrode 162 of the each of the light-emitting elements 160 are electrically connected to the first pad 141 and the second pad 142 of a corresponding pad group G2 respectively. The third conductive layer 170 includes a third conductive pattern 171. In a top view of the pixel structure 10C, at least a portion of the third conductive pattern 171 is located outside the pad groups G2.

When the laser L used to bond the light-emitting element 160 and the pad group G2 is irradiated toward the substrate 110 from the side where the light-emitting element 160 is located, at least a portion of the unshielded third conductive pattern 171 absorbs the laser L and heats up significantly. The first conductive pattern 121 disposed above the third conductive pattern 171 is affected by the third conductive pattern 171 and rises to a higher temperature. Thus, even if the first pad 141 is connected to the independent first conductive pattern 121, the first pad 141 can still be heated/insulated by the third conductive pattern 171 to have sufficient temperature so that the first electrode 161 of the light-emitting element 160 can be well bonded to the first pad 141.

In this embodiment, the pixel structure 10C further includes a fourth conductive pattern 190, which is disposed between the first insulating layer 130 and the second insulating layer 180 and is located outside an area of the pad groups G2. A material of the fourth conductive pattern 190 is different from a material of the first conductive pattern 120, and absorption of the laser L by the third conductive pattern 171 is greater than absorption of the laser L by the fourth conductive pattern 190. Compared with the adjacent fourth conductive pattern 190, the third conductive pattern 171 may absorb the laser L more effectively and produce a good heating/insulation effect on the pad group G2.

In this embodiment, an area of the third conductive pattern 171 outside the pad groups G2 is larger than a sum of areas of the first pads 141 and the second pads 142 of the pad groups G2. In other words, the third conductive pattern 171 has sufficient area that is not shielded and may produce significant heating/insulation effect on the first pad 141 and the second pad 142.

In this embodiment, in a top view of the pixel structure 10C, the first pads 141 and the second pads 142 of the pad groups G2 may selectively overlap the third conductive pattern 171 and be located within the third conductive pattern 171. In this embodiment, the third conductive layer 170 may further include a fifth conductive pattern 172, and the fifth conductive pattern 172 is shielded by components other than the first pad 141 and the second pad 142 (e.g., the fourth conductive pattern 190). In this embodiment, the third conductive pattern 171 used to heat/insulate the first pad 141 and the second pad 142 can be selectively disconnected from the fifth conductive pattern 172, but the disclosure is not limited thereto.

Comparing temperature distributions on the first pads 141 in FIG. 14 and FIG. 15 of the comparative example and FIG. 16 and FIG. 19 of this embodiment, it can be seen that under the same laser bonding conditions, the temperature of the first pads 141 of the pixel structure 10C of FIG. 16 and FIG. 19 of this embodiment is higher, the temperature of the first pads 141 of the pixel structure 10″ of FIG. 14 and FIG. 15 of the comparative example is lower, and the temperature on the first pads 141 and the second pads 142 of the pixel structure 10C of FIG. 16 and FIG. 19 of this embodiment are close to each other. It can be demonstrated that the design of the pixel structure 10C of the embodiment does help to increase the temperature of the pad group G2, which in turn improves the bonding yield between the light-emitting element 160 and the pad group G2.

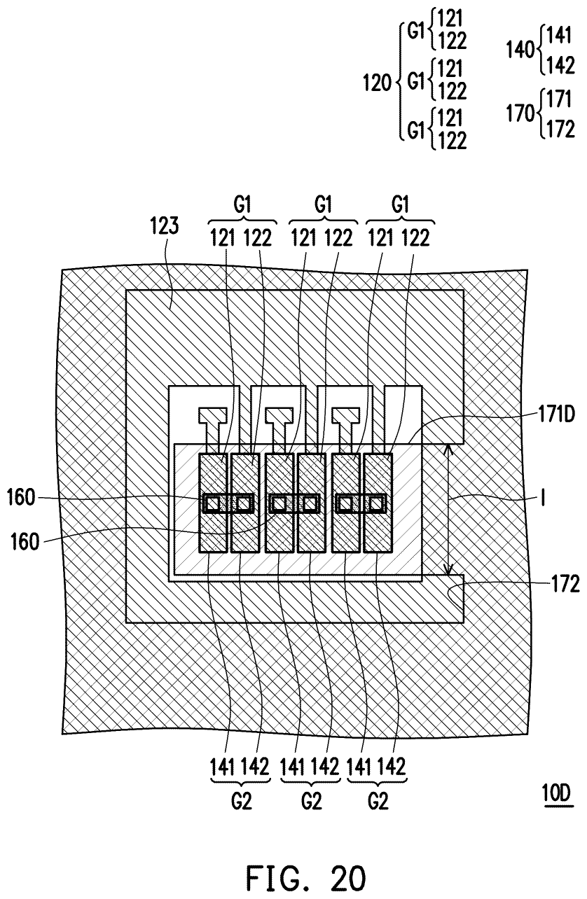

FIG. 20 is a schematic top view of a pixel structure according to an embodiment of the disclosure. A pixel structure 10D of this embodiment is similar to the pixel structure 10C. The difference between the two is that in the embodiment of FIG. 20, a third conductive pattern 171D can be connected to the fifth conductive pattern 172. A connection length 1 between the third conductive pattern 171D and the fifth conductive pattern 172 is less than one-half of a circumference of the third conductive pattern 171D.

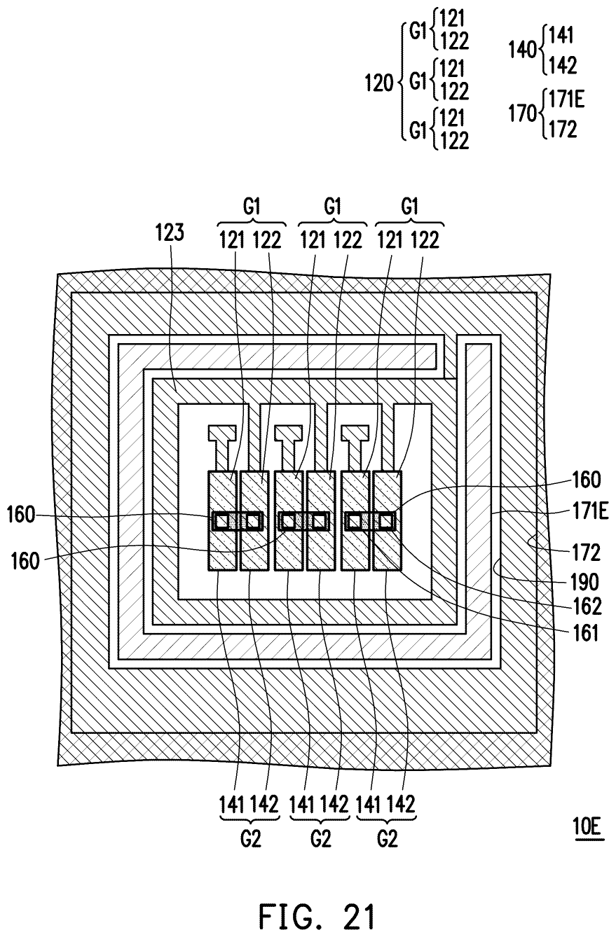

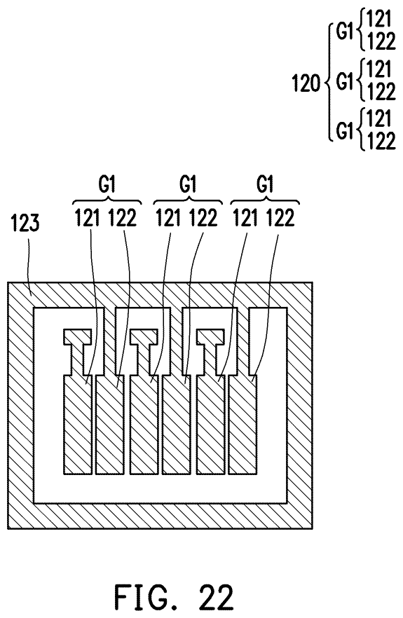

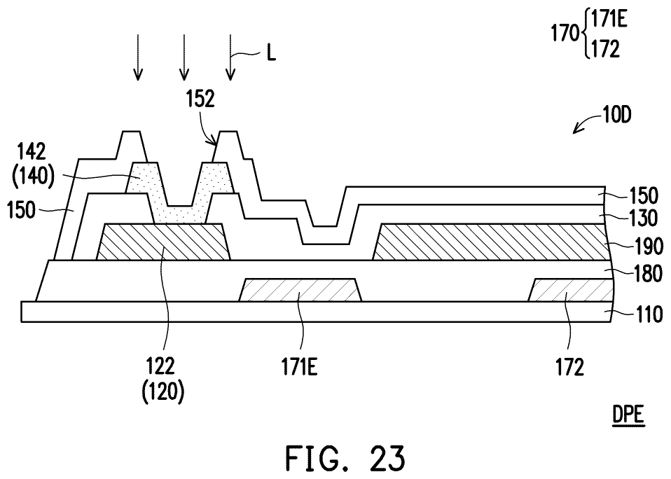

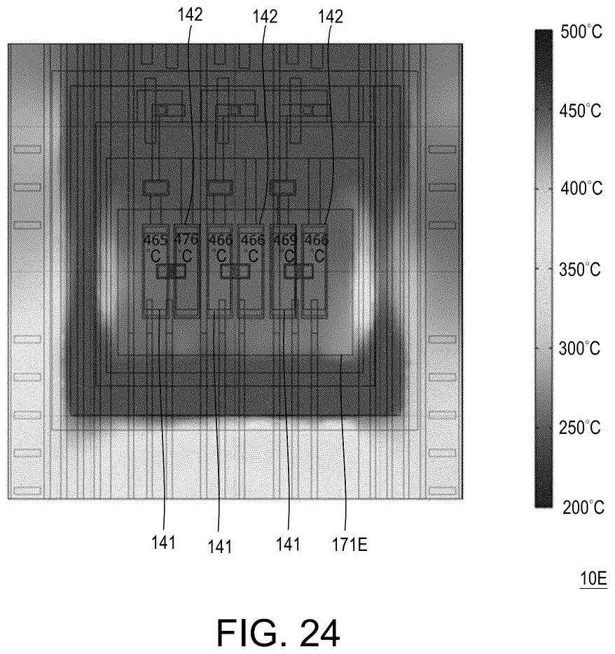

FIG. 21 is a schematic top view of a pixel structure according to another embodiment of the disclosure. FIG. 22 is a schematic top view of a first conductive layer of the pixel structure according to another embodiment of the disclosure. FIG. 23 is a schematic cross-sectional view of a display panel according to another embodiment of the disclosure. FIG. 23 shows a substrate 110, a third conductive layer 170, a second insulating layer 180, a first conductive layer 120, a fourth conductive pattern 190, a first insulating layer 130, a second conductive layer 140, and an insulating layer 150, while other components are omitted. FIG. 24 shows temperature distribution of multiple first pads and multiple second pads according to another embodiment of the disclosure in FIG. 21.

Referring to FIG. 21, FIG. 22, and FIG. 23, a display panel DPE and a pixel structure 10E thereof of this embodiment are similar to the display panel DP and the pixel structure 10C thereof. The difference between the two is that in this embodiment, in a top view of the pixel structure 10E, the first pads 141 and the second pads 142 of the pad groups G2 are staggered from the third conductive pattern 171E, and the third conductive pattern 171E surrounds the first pads 141 and the second pads 142 of the pad groups G2. In this embodiment, the third conductive pattern 171E may be selectively floating.

Comparing temperature distributions on the first pads 141 in FIG. 14 and FIG. 15 of the comparative example and FIG. 21 and FIG. 24 of this embodiment, it can be seen that under the same laser bonding conditions, the temperature of the first pads 141 of the pixel structure 10E of FIG. 21 and FIG. 24 of this embodiment is higher, the temperature of the first pads 141 of the pixel structure 10″ of FIG. 14 and FIG. 15 of the comparative example is lower, and the temperature on the first pads 141 and the second pads 142 of the pixel structure 10E of FIG. 21 and FIG. 24 of this embodiment are close to each other. It can be demonstrated that the design of the pixel structure 10E of the embodiment does help to increase the temperature of the pad group G2, which in turn improves the bonding yield between the light-emitting element 160 and the pad group G2.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A pixel structure, comprising:
a first conductive layer, comprising:
a plurality of conductive pattern groups, wherein each of the conductive pattern groups comprise a first conductive pattern and a second conductive pattern, and the first conductive pattern is island-shaped; and
a connection pattern, wherein second conductive patterns of the conductive pattern groups are directly connected to the connection pattern;
a first insulating layer, disposed on the first conductive layer;
a second conductive layer, disposed on the first insulating layer, wherein the second conductive layer comprises:
a plurality of pad groups, wherein each of the pad groups comprises a first pad and a second pad, the first pad and the second pad of the each of the pad groups are respectively overlapped with and electrically connected to the first conductive pattern and the second conductive pattern of the conductive pattern group, and the connection pattern is located outside an area of second pads of the pad groups; and
a plurality of light-emitting elements, wherein each of the light-emitting elements has a first electrode and a second electrode, and the first electrode and the second electrode of the each of the light-emitting elements are respectively electrically connected to the first pad and the second pad of the pad group;
wherein, in a top view of the pixel structure, the first pad is overlapped with the first conductive pattern and a portion of the connection pattern.

2. The pixel structure according to claim 1, wherein in a top view of the pixel structure, the first conductive pattern of the each of the conductive pattern groups is surrounded by the second conductive pattern of the conductive pattern group and the connection pattern.

3. The pixel structure according to claim 1, wherein the second conductive pattern of the conductive pattern group and the connection pattern have an opening surrounding the first conductive pattern of the conductive pattern group, and a circumference of the opening is greater than one-half of a circumference of the first conductive pattern of the conductive pattern group.

4. The pixel structure according to claim 1, wherein the second conductive pattern of the conductive pattern group and the connection pattern have an opening surrounding the first conductive pattern of the conductive pattern group, the opening has a gap with the first conductive pattern of the conductive pattern group, and a width of the gap is less than one-quarter of a circumference of the first conductive pattern of the conductive pattern group.

5. The pixel structure according to claim 1, wherein an overlapping area of the first conductive pattern of the conductive pattern group and the first pad is smaller than an overlapping area of the second conductive pattern of the conductive pattern group and the second pad.

6. A pixel structure, comprising:
a first conductive layer, comprising:
a plurality of conductive pattern groups, wherein each of the conductive pattern groups comprise a first conductive pattern and a second conductive pattern, and the first conductive pattern is island-shaped; and
a connection pattern, wherein second conductive patterns of the conductive pattern groups are directly connected to the connection pattern;
a first insulating layer, disposed on the first conductive layer;
a second conductive layer, disposed on the first insulating layer, wherein the second conductive layer comprises:
a plurality of pad groups, wherein each of the pad groups comprises a first pad and a second pad, the first pad and the second pad of the each of the pad groups are respectively overlapped with and electrically connected to the first conductive pattern and the second conductive pattern of the conductive pattern group, and the connection pattern is located outside an area of second pads of the pad groups;
a plurality of light-emitting elements, wherein each of the light-emitting elements has a first electrode and a second electrode, and the first electrode and the second electrode of the each of the light-emitting elements are respectively electrically connected to the first pad and the second pad of the pad group;
a third conductive layer, wherein the first conductive layer is disposed between the second conductive layer and the third conductive layer; and
a second insulating layer, disposed between the first conductive layer and the third conductive layer, wherein the third conductive layer comprises a third conductive pattern;
wherein, in a top view of the pixel structure, at least a portion of the third conductive pattern is located outside the pad groups.

7. The pixel structure according to claim 6 further comprising:
a fourth conductive pattern, disposed between the first insulating layer and the second insulating layer, and located outside an area of the pad groups, wherein a material of the fourth conductive pattern is different from a material of the first conductive layer, and absorption of a laser by the third conductive pattern is greater than absorption of the laser by the fourth conductive pattern.

8. The pixel structure according to claim 6, wherein an area of the third conductive pattern located outside the pad groups is greater than a sum of areas of a plurality of first pads and a plurality of second pads of the pad groups.

9. The pixel structure according to claim 6, wherein in a top view of the pixel structure, a plurality of first pads and a plurality of second pads of the pad groups are overlapped with the third conductive pattern and are located within the third conductive pattern.

10. The pixel structure according to claim 6, wherein in a top view of the pixel structure, a plurality of first pads and a plurality of second pads of the pad groups are staggered from the third conductive pattern, and the third conductive pattern surrounds the first pads and the second pads of the pad groups.
